(19) United States
(12) Patent Application Publication
(10) Pub. No.: US 2011/0234218 A1
(43) Pub. Date: Sep. 29, 2011

(54) INTEGRATED MULTI-AXIS HYBRID MAGNETIC FIELD SENSOR

(76) Inventor: Matthieu Lagouge, Wuxi (CN)

(21) Appl. No.: 12/730,717

(22) Filed: Mar. 24, 2010

(51) Int. Cl. G01R 33/02; G01R 33/07

(52) U.S. Cl. 324/247; 324/252; 324/251

(57) ABSTRACT

A multi-axis magnetic field sensing device combines two magnetoresistive sensors to measure the two orthogonal components X, Y of a magnetic field parallel to a system's plane and a Hall sensor to measure the Z component of the magnetic field substantially perpendicular to the system's plane. The two magnetoresistive sensors may be built together in one single chip and then stacked on top of a CMOS die embedding the Hall sensor and associated electronics for the signal processing management of the three sensors and the system's interface.

### STATEMENT REGARDING FEDERALLY SPONSORED RESEARCH OR DEVELOPMENT

N/A

### BACKGROUND OF THE INVENTION

Sensors to detect the earth's local magnetic field have been proposed and produced in large volume in the past. Some of these sensors feature two-axis sensing, while more sophisticated ones feature three-axis sensing. Different technologies are commonly used to detect such low strength magnetic fields. One of the two most common type of sensor is the magnetoresistive (MR) sensor.

The construction of a magnetoresistive sensor is well known where, generally, the resistivity of the sensor varies according to a local magnetic field oriented in the same plane as the magnetoresistance. “Barber-pole” structures are added to allow a sensing of the magnetic field along one axis to include direction, or vector, information. Magnetoresistive sensors have been used successfully in electronic compass applications, using two sensors to detect the magnetic field in the same plane as the surface they are mounted on, (X, Y), with an additional sensor mounted in a particular way so that the sensitive element is properly aligned to sense the component of the magnetic field orthogonal (Z) to the plane of the system.

In some known systems, the orthogonal (Z) axis sensitive sensor is mounted on a pre-cut printed circuit board (PCB) in the same plane as the other sensors and then folded orthogonally to that plane before being encapsulated. In some other known systems, the three sensors are encapsulated separately before being soldered on a PCB as a module. In this case, the orthogonal (Z) axis sensor is mounted along the axis orthogonal to the PCB directly rather than along the plane, as in, for example, U.S. Pat. No. 7,271,586. This particular orthogonal axis sensor mounting, however, can be technically challenging, and significantly increases the cost of manufacturing, as well as results in an increase in the thickness of the final product.

An alternative solution is to deposit magnetoresistive layers on an inclined plane on a substrate, as found in U.S. Patent Publication 2009/0027048. Microtechnology, however, is not well adapted to precisely control structure geometry on inclined planes, and renders the manufacturing of such sensors technically challenging.

An additional known approach consists of changing the fabrication process of the magnetic field sensor so that it becomes sensitive to the out-of-plane magnetic field as taught in U.S. Pat. No. 6,577,124. This solution increases both the cost and complexity of the device while requiring a trade-off, i.e., a decrease, of the resultant measurement sensitivity.

Another technology used in low magnetic field sensing is based on the Hall effect. As known, Hall sensors use the deviation of an electron flow caused by a local magnetic field to generate a voltage difference across a conductive element in a direction orthogonal to the current path and the magnetic field. Hall sensors generally consume more power than magnetoresistive sensors due to the high current required to generate a measurable Hall voltage.

Recently, the number of applications where it is desirable to have a low-cost three-axis magnetic field sensor capable of accurately measuring the earth's local magnetic field integrated in a small package has significantly increased. When produced in large volume, these devices can be embedded in consumer products such as mobile phones and navigation systems, for example, and are used in combination with the Global Positioning System (“GPS”) as well as other products where small size and low cost per unit are important.

There is a need, therefore, for a low profile, inexpensive, but high performance, three-axis magnetic field sensor that can be produced in large volume using a simple manufacturing process.

### BRIEF SUMMARY OF THE INVENTION

The present invention proposes to combine two magnetoresistive sensors to measure the two components X, Y of the magnetic field parallel to the system's plane and a Hall sensor for the Z component of the magnetic field orthogonal to the system's plane.

In one embodiment, the two magnetoresistive sensors are built together in one single chip, and then stacked on top of a CMOS die embedding the Hall sensor and associated electronics for the signal processing management of the three sensors and the system's interface.

In such an arrangement, the three-axis sensors can provide sufficient sensitivity within a very low profile device while keeping the unit costs low and avoiding manufacturing complexity as compared to single technology solutions.

### BRIEF DESCRIPTION OF THE SEVERAL VIEWS OF THE DRAWINGS

Various aspects of at least one embodiment of the present invention are discussed below with reference to the accompanying figures. It will be appreciated that for simplicity and clarity of illustration, elements shown in the drawings have not necessarily been drawn accurately or to scale. For example, the dimensions of some of the elements may be exaggerated relative to other elements for clarity or several physical components may be included in one functional block or element. Further, where considered appropriate, reference numerals may be repeated among the drawings to indicate corresponding or analogous elements. For purposes of clarity, not every component may be labeled in every drawing. The figures are provided for the purposes of illustration and explanation and are not intended as a definition of the limits of the invention. In the figures:

FIG. 1 is a functional block diagram of a three-axis magnetic sensor according to a first embodiment of the present invention;

FIG. 2 is a schematic view of the three-axis magnetic sensor system according to the first embodiment of the present invention;

FIGS. 3A and 3B are, respectively, a schematic view and a functional block diagram, of a three-axis magnetic sensor system according to a second embodiment of the present invention;

FIGS. 4A and 4B are, respectively, a schematic view and a functional block diagram, of a three-axis magnetic sensor system according to a third embodiment of the present invention;

FIG. 5 is a schematic view of a three-axis magnetic sensor system reflecting a variation of the embodiment shown in FIGS. 4A and 4B; and

FIGS. 6A and 6B are, respectively, a schematic view and a functional block diagram, of a three-axis magnetic sensor system in accordance with a fourth embodiment of the present invention.

### DETAILED DESCRIPTION OF THE INVENTION

Embodiments of the present invention propose combinations of different sensor technologies, i.e., Hall effect and magnetoresistive, integrated in a single package to combine the advantages of the different technologies.

As a general overview, in various embodiments of the present invention, as will be explained in more detail below, two magnetoresistive sensors are used to measure planar components of the earth's magnetic field with respect to a plane defined by a substrate of the packaging. These two magnetoresistive sensors measure magnetic fields along two axes that are orthogonal to each other and co-planar, generally referred to as the X and Y directions or E_{X} and E_{Y}. A Hall sensor, i.e., one that uses the Hall effect to measure a magnetic field along an axis, is used to measure the magnetic field that is orthogonal to the plane defined by the substrate of the packaging, generally referred to as the Z direction, or E_{Z}. Various embodiments will be described below to provide more details about the different combinations and arrangements of the sensors and supporting circuitry.

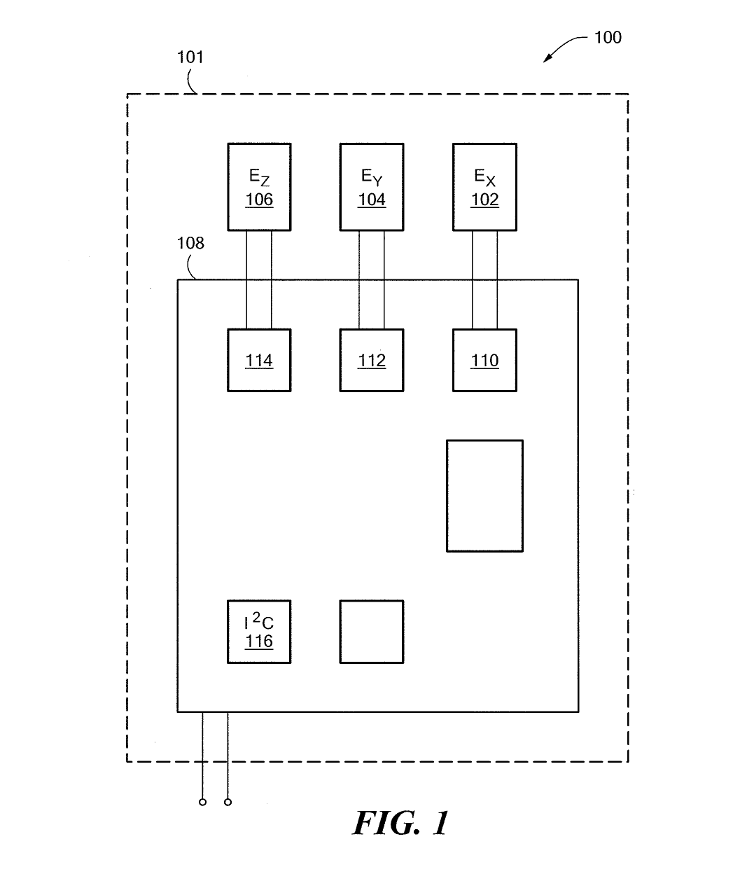

One embodiment of the present invention will now be described with respect to the functional block diagram shown in FIG. 1. A three-axis sensor 100 includes a planar substrate 101, for example, a printed circuit board (PCB) either flexible or not, that defines a plane with respect to which two magnetoresistive sensors 102, 104, and a Hall sensor 106 are mounted. A mixed-signal ASIC 108 interfaces with the three separate sensors 102-106, i.e., one for each of the X, Y and Z axes, to provide a complete magnetic field measurement system.

The two magnetoresistive sensors 102, 104 are oriented with respect to one another and the plane defined by the substrate 101 to measure orthogonal magnetic fields, i.e., E_{X} and E_{Y}. The magnetoresistive sensors 102, 104 may be of the same construction and, in one embodiment, as detailed below, may be the same model of device. The Hall sensor is positioned to measure the Z direction, i.e., E_{Z}.

In one embodiment, the ASIC 108 may be designed with 0.18 micrometer (μm) CMOS technology having a combination of metal layers and polysilicon layers. Further, the differential signals from each of the magnetoresistive sensors 102 and 104 may be fed, respectively, into two signal processing channels 110, 112 that provide, among other functions, low noise amplification, offset adjustment, sensitivity adjustment, temperature compensation and analog to digital conversion. The ASIC 108 may be designed such that the differential signal from the Hall sensor 106 is fed into a processing channel 114 to process those signals as is known in the art. The ASIC 108 may include an I²C digital communications module 116, operated in FAST mode, i.e., up to a 400 KHz clock rate, that eliminates the need for an external analog digital converter and provides a two-pin I²C interface to an external MCU (not shown).

One of ordinary skill in the art will understand that any one of a number of different technologies may be used to design a mixed-signal ASIC to operate in accordance with the embodiments described herein. Further, while an I²C interface has been described, any one or more of many known interfaces may be implemented instead. These interfaces can include, for example, one or more digital interrupt pins to communicate with an external MCU. The selection of a digital interface for the ASIC 108 is a design choice depending upon the needs of the system into which the ASIC will be placed.

The substrate 101, sensors 102-106 and the ASIC 108 may be covered with a potting material in order to provide a hybrid “system on a chip.” Thus, this complete three-axis sensor 100 can be inserted as a single part in a system that requires three-axis magnetic field measurements. Of course, although not shown, appropriate other connections would be provided such as power and ground/return.

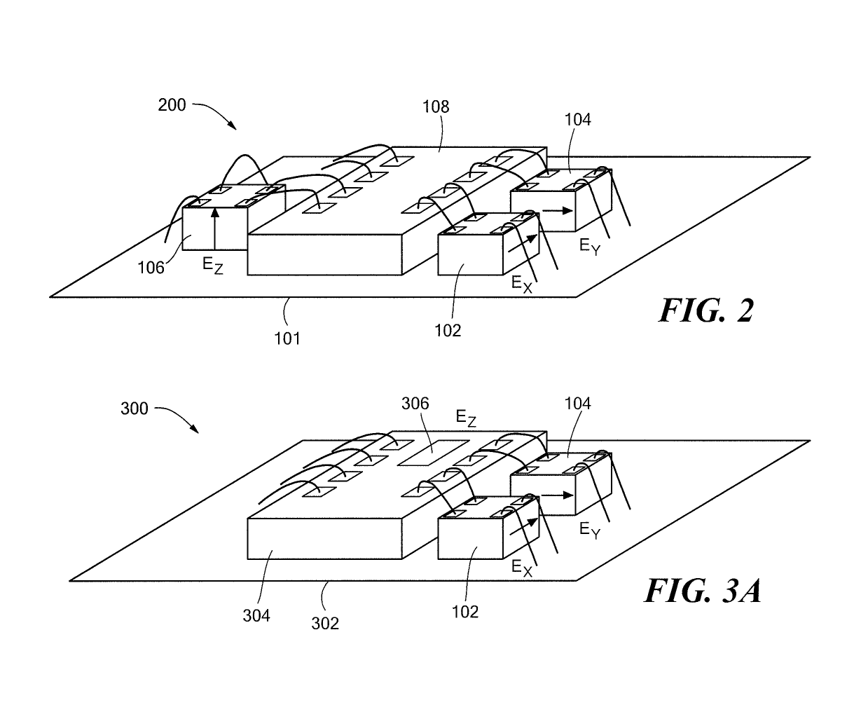

Referring now to FIG. 2, a three-axis sensor according to the embodiment of the present invention presented in FIG. 1 will be described. A system 200 is made of a PCB 101 on which is mounted a combination of chips. Two magnetoresistive (MR) sensor elements 102 and 104, arranged so that each one measures a component of the magnetic field orthogonal to the other, i.e., Eₓand E_{y}, and coplanar with the PCB 101. The ASIC 108 integrates the electronics circuits for excitation of the MR sensors 102, 104 and the signal processing units, including the system interface, as described above. The Hall sensor element 106 is sensitive to the component of the magnetic field, E_{z} orthogonal to the plane made by the PCB 101.

In this system 200, the three sensors 102, 104 and 106 can use standard mounting processes on the PCB 101, e.g., using a die attach paste and wirebonding. The system 200 can further be encapsulated inside an encapsulant material using a molding or analog method to make a complete device. Some benefits of having all the chips mounted with respect to a plane include the possibility to thin down, i.e., reduce the height of the chips, to obtain a small profile for the system 200.

Embodiments of the present invention are not limited to the use of a PCB and encapsulant, as any encapsulant can be replaced by a ceramic package having a cavity, some pads, and a lid.

Those skilled in the art will also note that a two axis magnetic sensor system having one axis parallel to the plane made by the PCB 101 and one axis orthogonal to the plane made by the PCB 101 can be realized by removing, or disabling, one of the two magnetoresistive sensor chips 102, 104, for a specific application.

Finally, those skilled in the art will also note that the ASIC 108 can additionally integrate other types of CMOS compatible sensors, such as, for example, accelerometers and pressure sensors, to form a multi-sensor structure while maintaining the benefits of the present invention.

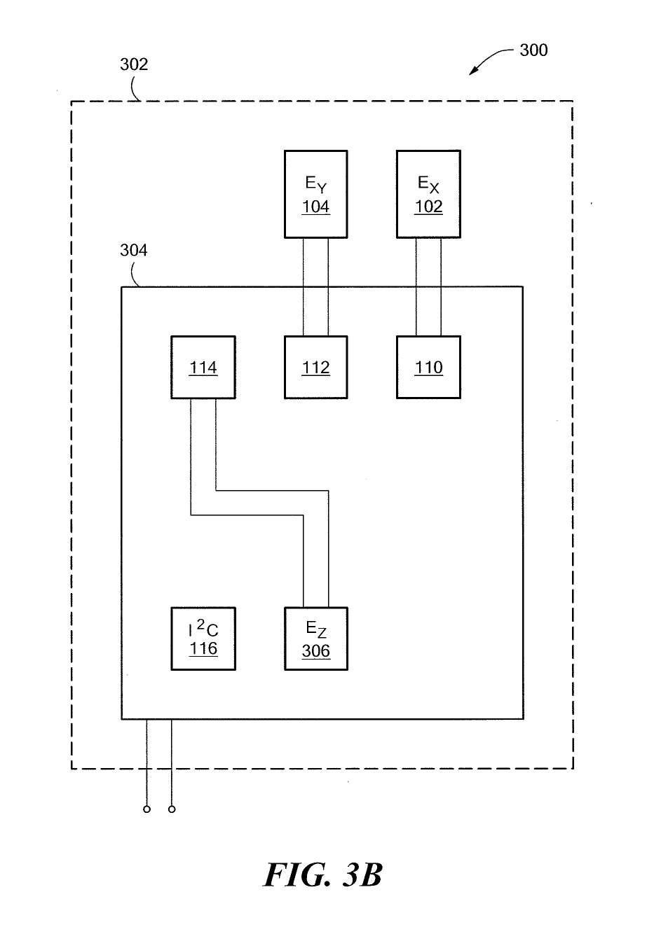

A three-axis magnetic field sensor system in a package according to a second embodiment of the present invention will be described with respect to FIGS. 3A and 3B. In this embodiment, a system 300 is made of a PCB 302 on which are mounted two magnetoresistive sensors 102 and 104 in the same way as the first embodiment shown in FIG. 2. An ASIC 304 integrates the electronic circuits for excitation and signal processing of the two magnetoresistive sensors 102, 104, and is combined with an integrated Hall sensor area 306 that is sensitive to the component of the magnetic field E_{z} orthogonal to the plane defined by the PCB 302. In this embodiment, the integration of the Hall sensor area 306 into the ASIC 304 allows for a smaller size for the system and reduces assembly complexity by eliminating die attach and wirebonding steps for the Hall sensor of the first embodiment while maintaining the benefits of having the devices mounted in a standard way.

Similar to the discussion with respect to the first embodiment, the packaging, two axis solution, and multi-sensor system modifications are also applicable as variations of the second embodiment of the present invention shown in FIGS. 3A and 3B.

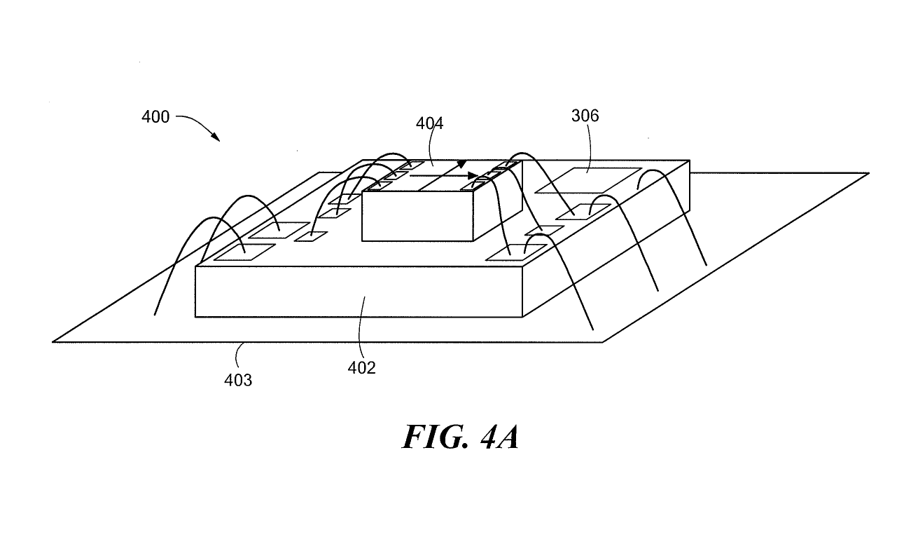

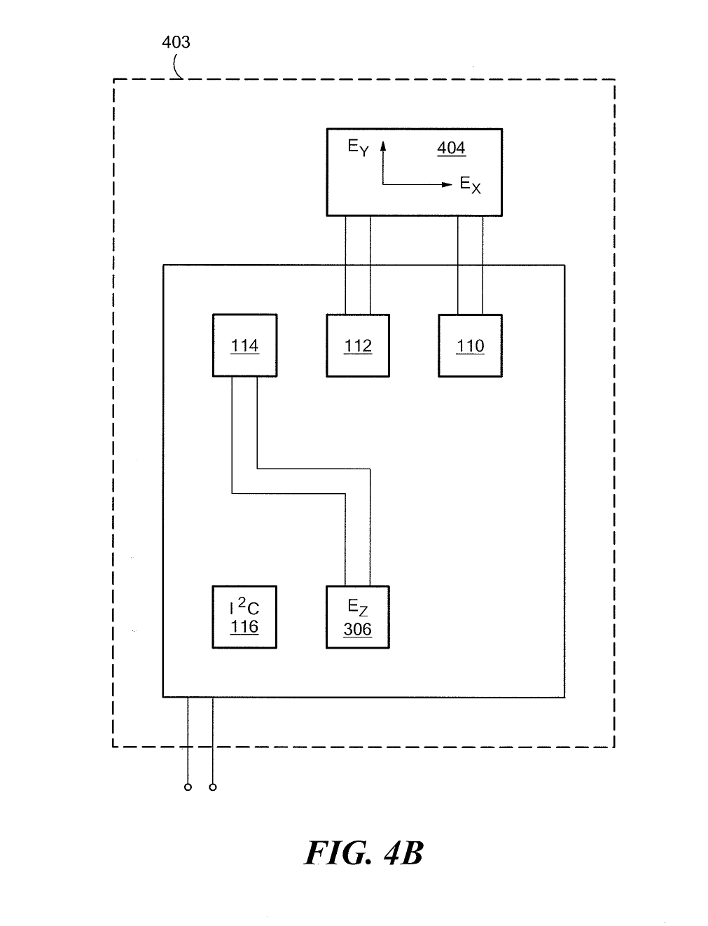

A three-axis magnetic field sensor system according to a third embodiment of the present invention is presented in FIGS. 4A and 4B. In this embodiment, a system 400 includes an ASIC 402 having a Hall sensor element 306, integrated in the same way as the ASIC 304 shown in FIG. 3A, mounted on a PCB 403. A two-axis magnetoresistive device 404 that combines two sensor elements, each able to measure a respective component, Eₓ, E_{y}, of the magnetic field parallel to the plane made by the PCB 403 and orthogonal to each other, is provided. The magnetoresistive sensor 404 is mounted on top of the ASIC 402, commonly referred to as “stack packaging.”

Those skilled in the art will notice that such a sensor 404, combining two orthogonal magnetoresistive sensor elements, can be used in other embodiments of the present invention to replace the two magnetoresistive sensors.

Having a stack configuration, as shown in FIG. 4A, allows a further reduction of the lateral size of the system 400 while also keeping the benefits of the other embodiments of the present invention. Additionally, considering the possibility to thin down the different devices, the final system can still show a very low profile compared to most known three-axis magnetic sensors solutions.

The same remarks concerning the package, two axis solution, and multi-sensor systems mentioned with respect to the previous embodiments are still valid with respect to this embodiment.

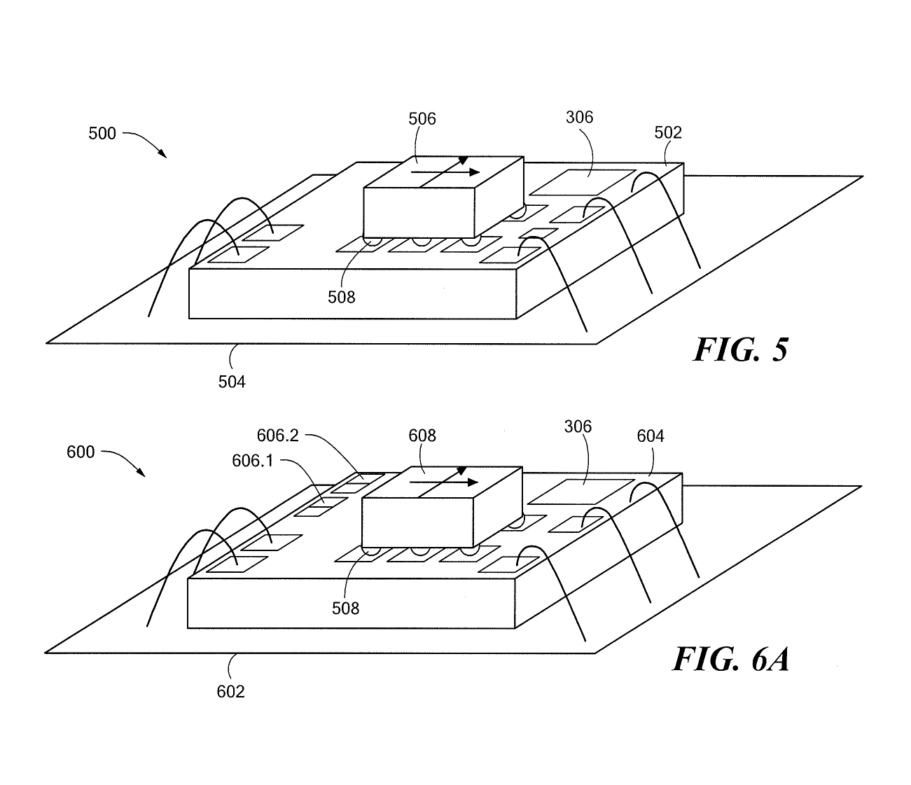

A three-axis magnetic sensor system 500, according to a modification of the third embodiment of the present invention, is presented in FIG. 5. A system 500 includes an ASIC 502 incorporating a Hall sensor element 306 mounted on a PCB 504. The ASIC 502 integrates the electronic circuits for excitation and signal processing of the sensor elements, including the interface, and is mounted on top of a PCB 504. A magnetoresistive sensor 506, similar to the MR sensor 404 described in FIG. 4A, is mounted on top of the ASIC 502 using a flip-chip method that consists of mounting the MR sensor 506 upside down and linking it with the ASIC 502 using soldering balls 508 on the MR sensor 506 and specific respective pads on the ASIC 502.

In this embodiment, the assembly complexity linked with the wirebonding together of the different devices is removed, and the total thickness is reduced by the height of the wires above the sensor surface compared to the device 400 in FIG. 4A.

Those skilled in the art will notice that a flip-chip method can be used in the previous embodiments in which the chips are mounted side-by-side so as to replace the wirebonding. Many combinations of devices and sensors mounted using the flip-chip method, or the die attach and wirebonding method, are possible and can be selected depending on different optimizations required by the final device.

Those skilled in the art will also notice that it is possible to keep a stack assembly of the different devices, either by die attach and wirebonding or flip-chip, and use some vias to connect the ASIC to the PCB to further reduce the lateral size of the complete system.

The same remarks with respect to the previous embodiments regarding the package, two axis solution and multi-sensor systems mentioned with respect to the previous embodiments are still valid in the current embodiment.

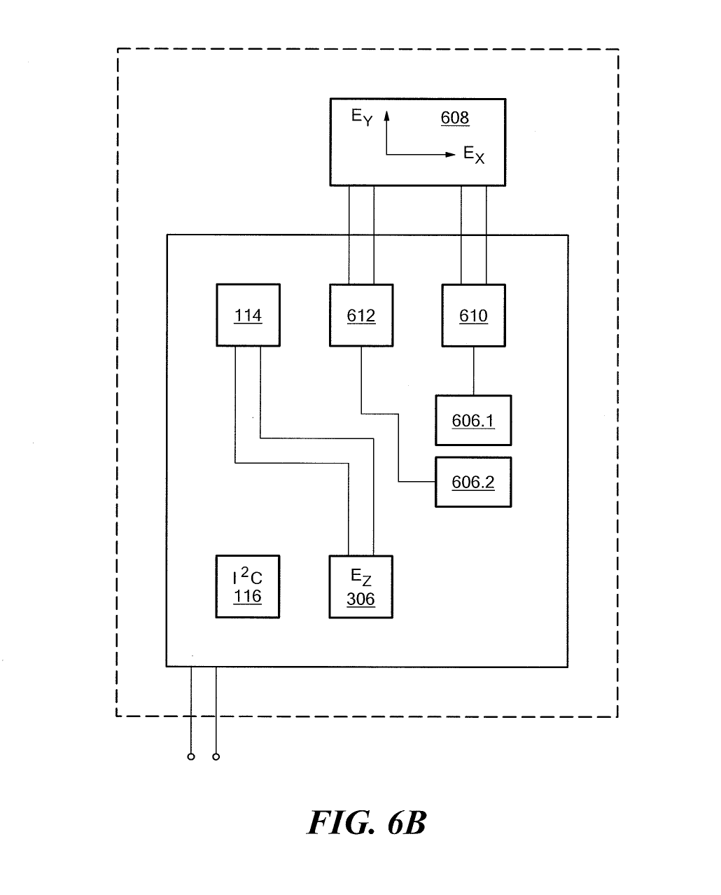

A schematic view of a magnetic field sensor system according to a fourth embodiment of the present invention will now be described with respect to FIGS. 6A and 6B. A three-axis system 600 comprises a PCB 602 on which is mounted an ASIC 604. The ASIC 604 includes the electronic circuits for excitation and signal processing of the three sensors elements: a Hall sensor element 306 sensitive to the magnetic axis E_{z} orthogonal with respect to the plane defined by the PCB 602, and two Hall element switches 606.1, 606.2, able to, respectively, measure the directions of the magnetic field components Eₓ and E_{y} parallel to the plane of the PCB 602 and orthogonal to one another. A magnetoresistive sensor 608 is stacked on top of the ASIC 604 using the flip-chip method via solder balls 508. The MR sensor 608 integrates two magnetoresistive sensors that are each sensitive to a magnitude, but not the direction, of the respective component of the magnetic fields Eₓ, E_{y} parallel to the plane of the PCB 602 and orthogonal to each other.

Each of the two magnetoresistive sensors in the MR device 608 has a high sensitivity for the amplitude of the component of the magnetic field along the respective axis but cannot detect the direction of the detected magnetic field. The respective direction is determined by the two Hall elements switches 606.1 and 606.2.

By eliminating the need for direction detection in the magnetoresistive sensors 608, the fabrication process is simpler and less expensive because there are no “barber pole” structures. The ASIC 604 combines the information from the two Hall switches 606.1, 606.2, in corresponding processing sections 610 and 612 with the information from the MR device 608 similar to that which is taught in U.S. Pat. No. 6,707,293 to detect the direction of the magnetic fields.

The same remarks as before concerning the packaging, two axis solutions, multi-sensor system, flip-chip combinations and through silicon via connections with the PCB 602 are applicable to this embodiment of the present invention.

In the above-described embodiments of the present invention, the combinations of different Hall sensor elements and magnetoresistive sensors allows for a low cost, small scale and high precision three-axis magnetic sensor.

Having thus described several features of at least one embodiment of the present invention, it is to be appreciated that various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A multi-axis magnetic field sensing device, comprising:
a first planar substrate that defines a first plane;
a first magnetoresistive (MR) sensor oriented and configured to sense at least a magnitude of a magnetic field oriented along a first axis parallel to the first plane; and
a Hall effect sensor oriented and configured to sense a magnetic field oriented along a Z-axis substantially perpendicular to the first plane,
wherein the first MR sensor and the Hall effect sensor are mechanically coupled to the first planar substrate.

2. The multi-axis magnetic field sensing device of claim 1, wherein:
the first planar substrate is a printed circuit board (PCB); and
at least one of the first MR sensor and the Hall effect sensor is mounted directly on the PCB.

3. The multi-axis magnetic field sensing device of claim 1, further comprising:
an ASIC device configured to interface with, and coupled to, each of the first MR sensor and the Hall effect sensor.

4. The multi-axis magnetic field sensing device of claim 3, wherein:
the first planar substrate is a PCB;
the ASIC device is directly mounted on the PCB; and
at least one of the first MR sensor and the Hall effect sensor is mounted on the PCB.

5. The multi-axis magnetic field sensing device of claim 1, wherein the first planar substrate is a PCB, the device further comprising:
an ASIC device configured to interface with, and coupled to, the first MR sensor,
wherein the Hall effect sensor is incorporated in the ASIC device, and
wherein the ASIC device and the first MR sensor are directly mounted on the PCB.

6. The multi-axis magnetic field sensing device of claim 1, further comprising:
a second MR sensor oriented and configured to sense at least a magnitude of a magnetic field along a second axis parallel to the first plane, the second axis being orthogonal to the first axis.

7. The multi-axis magnetic field sensing device of claim 6, wherein the first and second MR sensors are incorporated into a single 2-axis sensor device while maintaining their orientations with respect to each other.

8. The multi-axis magnetic field sensing device of claim 7, wherein the first planar substrate is a PCB, the device further comprising:
an ASIC configured to interface with, and coupled to, the single 2-axis device,
wherein the ASIC and the single 2-axis sensor device and the Hall effect sensor are mounted on the PCB.

9. The multi-axis magnetic field sensing device of claim 7, wherein the first planar substrate is a PCB, the device further comprising:
an ASIC configured to interface with, and coupled to, the single 2-axis sensor device,
wherein the Hall effect sensor is incorporated into the ASIC device, and
wherein the single 2-axis sensor device is mounted on the ASIC device and the ASIC device is mounted directly on the PCB.

10. The multi-axis magnetic field sensing device of claim 6, wherein each of the first and second MR sensors senses only a magnitude of the magnetic field for its respective axis, the sensing device further comprising:
an ASIC device configured to interface with, and which is coupled to, each of the first and second MR sensors, wherein the Hall effect sensor is incorporated into the ASIC device; and
first and second Hall effect switches incorporated into the ASIC, wherein each of the first and second Hall effect switches determines a direction of a magnetic field along the first and second axes, respectively.

11. The multi-axis magnetic field sensing device of claim 6, wherein each of the first and second MR sensors is further configured to sense a direction of the magnetic field oriented along the first and second axes, respectively.

12. The multi-axis magnetic field sensing device of claim 11, wherein each of the first and second MR sensors further comprises a barber pole structure.

13. The multi-axis magnetic field sensing device of claim 1, wherein the first MR sensor is further configured to sense a direction of the magnetic field oriented along the first axis.

14. The multi-axis magnetic field sensing device of claim 13, wherein the first MR sensor further comprises a barber pole structure.

15. The multi-axis magnetic field sensing device of claim 1, further comprising:
a second MR sensor oriented and configured to sense at least a magnitude of a magnetic field oriented along a second axis parallel to the first plane, the second axis being orthogonal to the first axis; and
an ASIC device configured to interface with, and coupled to, each of the first and second MR sensors and the Hall effect sensor.

16. The multi-axis magnetic field sensing device of claim 15, wherein:
the first planar substrate is a PCB;
the ASIC device is mounted on the PCB; and
at least one of the first and second MR sensors and the Hall effect sensor is mounted on the PCB.

17. The multi-axis magnetic field sensing device of claim 15, wherein the Hall effect sensor is incorporated into the ASIC device.

18. The multi-axis magnetic field sensing device of claim 1, wherein the first planar substrate is a PCB, the device further comprising:
an ASIC device configured to interface with, and coupled to, the first and second MR sensors,
wherein the Hall effect sensor is incorporated into the ASIC device, and
wherein the ASIC device and the first and second MR sensors are mounted on the PCB.

19. The multi-axis magnetic field sensing device of claim 18, wherein each of the first and second MR sensors is further configured to sense a direction of the magnetic field oriented along the first and second axes, respectively.

20. The multi-axis magnetic field sensing device of claim 19, wherein each of the first and second MR sensors further comprises a barber pole structure.

21. A multi-axis magnetic field sensing device, comprising:
a first magnetoresistive (MR) sensor oriented and configured to sense a magnetic field along a first axis in a first plane;
a second MR sensor oriented and configured to sense a magnetic field along a second axis in the first plane, the second axis being orthogonal to the first axis; and
a Hall effect sensor oriented and configured to sense a magnetic field along a third axis orthogonal to the first plane,
wherein the first and second MR sensors and the Hall effect sensor are coupled to a first planar substrate that defines the first plane.

22. The multi-axis magnetic field sensing device of claim 21, wherein:
the first planar substrate is a printed circuit board (PCB); and
at least one of the first and second MR sensors and the Hall effect sensor is mounted on the PCB.

23. The multi-axis magnetic field sensing device of claim 21, further comprising:
an ASIC device configured to interface with, and coupled to, each of the first and second MR sensors and the Hall effect sensor.

24. The multi-axis magnetic field sensing device of claim 23, wherein:
the first planar substrate is a PCB;
the ASIC device is mounted on the PCB; and
at least one of the first and second MR sensors and the Hall effect sensor is mounted on the PCB.

25. The multi-axis magnetic field sensing device of claim 21, wherein the first planar substrate is a PCB, the device further comprising:
an ASIC device configured to interface with, and coupled to, the first and second MR sensors,
wherein the Hall effect sensor is incorporated into the ASIC device, and
wherein the ASIC device and the first and second MR sensors are mounted on the PCB.

26. The multi-axis magnetic field sensing device of claim 21, wherein the first and second MR sensors are incorporated into a single 2-axis device while maintaining their orientations with respect to each other.

27. The multi-axis magnetic field sensing device of claim 26, wherein the first planar substrate is a PCB, the device further comprising:
an ASIC configured to interface with, and coupled to, the single 2-axis sensor device,
wherein the ASIC and single 2-axis sensor device and the Hall effect sensor are mounted on the PCB.

28. The multi-axis magnetic field sensing device of claim 26, wherein the first planar substrate is a PCB, the device further comprising:
an ASIC configured to interface with, and coupled to, the single 2-axis sensor device,
wherein the Hall effect sensor is incorporated into the ASIC device, and
wherein the single 2-axis sensor device is mounted on the ASIC device and the ASIC device is mounted on the PCB.

29. The multi-axis magnetic field sensing device of claim 21, wherein each of the first and second MR sensors comprises a barber pole structure.

30. The multi-axis magnetic field sensing device of claim 21, wherein each of the first and second MR sensors is configured to sense only a magnitude of its respective magnetic field and not a direction thereof, the sensing device further comprising:
an ASIC device configured to interface with, and coupled to, each of the first and second MR sensors, wherein the Hall effect sensor is incorporated into the ASIC device; and
first and second Hall effect switches incorporated into the ASIC, wherein each of the first and second Hall effect switches is configured to determine a direction of a magnetic field along the first and second axes, respectively.
